(19) United States
(12) Patent Application Publication
(10) Pub. No.: US 2024/0074318 A1
(43) Pub. Date: Feb. 29, 2024

(54) TRANSDUCER AND METHOD OF PRODUCING TRANSDUCER

(71) Applicant: SONY GROUP CORPORATION, TOKYO (JP)

(72) Inventors: YUSAKU KATO, TOKYO (JP); AKIHIRO NAKATA, TOKYO (JP); RYO IWAMURO, TOKYO (JP); DAISUKE YAMAMOTO, TOKYO (JP); HIROYUKI MITSUHASHI, TOKYO (JP); YOSHIO GOTO, TOKYO (JP)

(21) Appl. No.: 18/259,410

(22) PCT Filed: Dec. 9, 2021
(86) PCT No.: PCT/JP2021/045272

§ 371 Date: Jun. 27, 2023

(30) Foreign Application Priority Data
Jan. 6, 2021 (JP) 2021-001101

(51) Int. Cl. H10N 30/50; H10N 30/057; H10N 30/857

(52) U.S. Cl. CPC H10N 30/508; H10N 30/057; H10N 30/505; H10N 30/857; G03B 9/02

(57) ABSTRACT

[Object] To provide a transducer capable of providing a high degree of freedom in deformation and suppressing a risk of breakage and a method of producing the transducer. [Solving Means] In order to achieve the above-described object, a transducer according to an embodiment of the present technology includes an elastomer. The elastomer extends along a predetermined axis direction, and has both end portions in which at least two electrodes having followability are disposed on both sides around a predetermined axis in the predetermined axis direction, the both end portions being elongated to be folded in a direction perpendicular to the predetermined axis. This makes it possible to provide a high degree of freedom in deformation and to suppress a risk of breakage.

### TECHNICAL FIELD

The present technology relates to a transducer that changes an opening or the like, and a method of producing the transducer.

### BACKGROUND ART

Patent Literature 1 discloses a device for controlling a fluid flow. The device is configured such that each of one or more transducers comprises at least two electrodes and an electroactive polymer in electrical communication with the two electrodes, and a portion of the electroactive polymer deflects from a first position to a second position in response to a change in an electric field. The device comprises at least one surface in contact with a fluid and operatively coupled to the one or more transducers in which a deflection of the portion of the electroactive polymer causes a change in a characteristic of the fluid that is transmitted to the fluid via the one surface. As a result, a high-performance polymer is realized in a fluid control application example (paragraphs to of specification, FIG. 2, etc. of Patent Literature 1).

### CITATION LIST

### Patent Literature

Patent Literature 1: Japanese Unexamined Patent Application Publication No. 2005-527178

### DISCLOSURE OF INVENTION

### Technical Problem

Thus, there is a need for a technology capable of providing a high degree of freedom in deformation and suppressing a risk of breakage.

In view of the above-described circumstances, an object of the present technology is to provide a transducer capable of providing a high degree of freedom in deformation and suppressing a risk of breakage and a method of producing the transducer.

### Solution to Problem

In order to achieve the above-described object, a transducer according to an embodiment of the present technology includes an elastomer.

The elastomer extends along a predetermined axis direction, and has both end portions in which at least two electrodes having followability are disposed on both sides around a predetermined axis in the predetermined axis direction, the both end portions being elongated so as to be folded in a direction perpendicular to the predetermined axis.

In this transducer, the elastomer extends along a predetermined axis direction, and has both end portions in which at least two electrodes having followability are disposed on both sides around a predetermined axis in the predetermined axis direction, the both end portions being elongated so as to be folded in the direction perpendicular to the predetermined axis. This makes it possible to provide a high degree of freedom in deformation and to suppress a risk of breakage.

The transducer may further include a central portion in a region different from the both end portions of the elastomer. In this case, the central portion may be elongated so as to approach the predetermined axis by energizing the electrodes.

The both end portions located in the same direction with respect to the predetermined axis may be elongated so as to be substantially parallel to the predetermined axis by energizing the electrodes.

The elastomer may have a donut shape viewed from the predetermined axis direction when the both end portions are elongated so as to be folded in the direction perpendicular to the predetermined axis.

The elastomer may have a cylindrical shape extending along the predetermined axis direction and have an opening in the predetermined axis direction. In this case, the central portion may be elongated so as to change a diameter size of the opening by energizing the electrodes.

A method of producing a transducer according to one embodiment of the present technology performs the following steps:
a first step of depositing an electrode material in a direction perpendicular to a predetermined axis with respect to a cylindrical core material extending along the predetermined axis;
a second step of depositing an elastomer on the electrode material in the direction perpendicular to the predetermined axis; and
a third step of repeating the first step and the second step to deposit the electrode material and the elastomer.

In the third step, the electrode material and the elastomer may be deposited at different positions in the predetermined axis direction.

The method of producing the transducer may further include a fourth step of removing the core material after the third step is completed.

### BRIEF DESCRIPTION OF DRAWINGS

FIG. 1 is a diagram schematically showing a DEA.

FIG. 2 is a diagram showing a donut-shaped DEA as compared to the present invention. [ [symbol] 1]

FIG. 3 is a diagram specifically showing elongating and driving of the DEA. [ [symbol] 2]

FIG. 4 is a diagram showing a production process of the DEA. [ [symbol] 3]

FIG. 5 is a schematic diagram showing an exemplary configuration of a transducer including the DEA. [ [symbol] 4]

FIG. 6 is a schematic diagram in a case where the DEA includes a plurality of layers of elastomers. [ [symbol] 5]

FIG. 7 is a schematic diagram showing an earphone deformable in an ear hole. [ [symbol] 6]

FIG. 8 is a schematic diagram showing a method of elongating and producing the transducer. [ [symbol] 7]

### MODE(S) FOR CARRYING OUT THE INVENTION

Hereinafter, embodiments according to the present technology will be described below with reference to the drawings.

[Driving DEA (Dielectric Elastomer Actuator)]

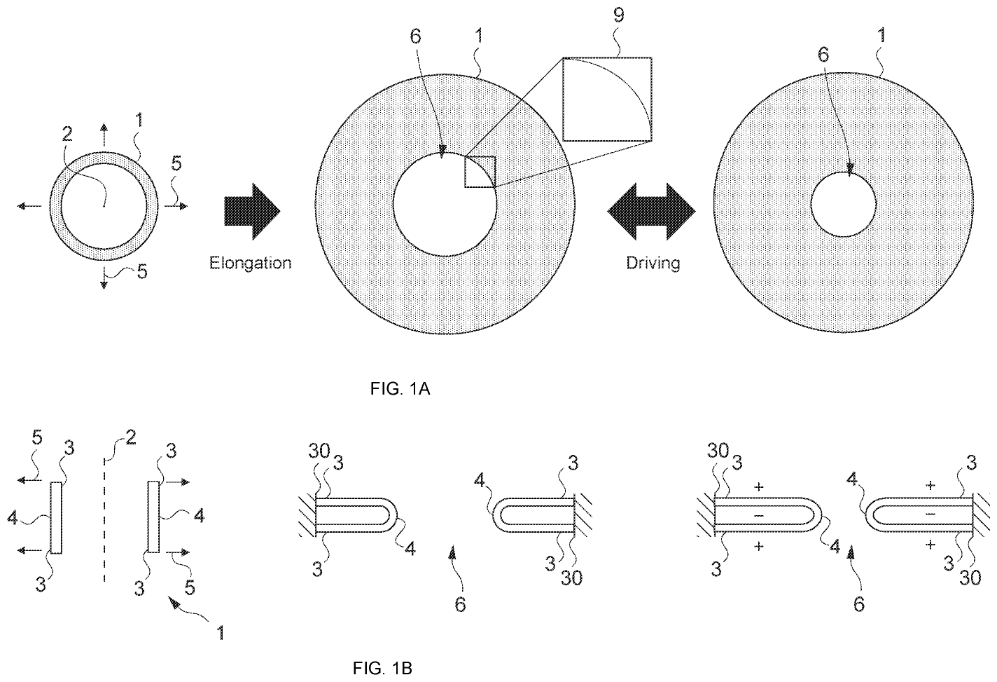

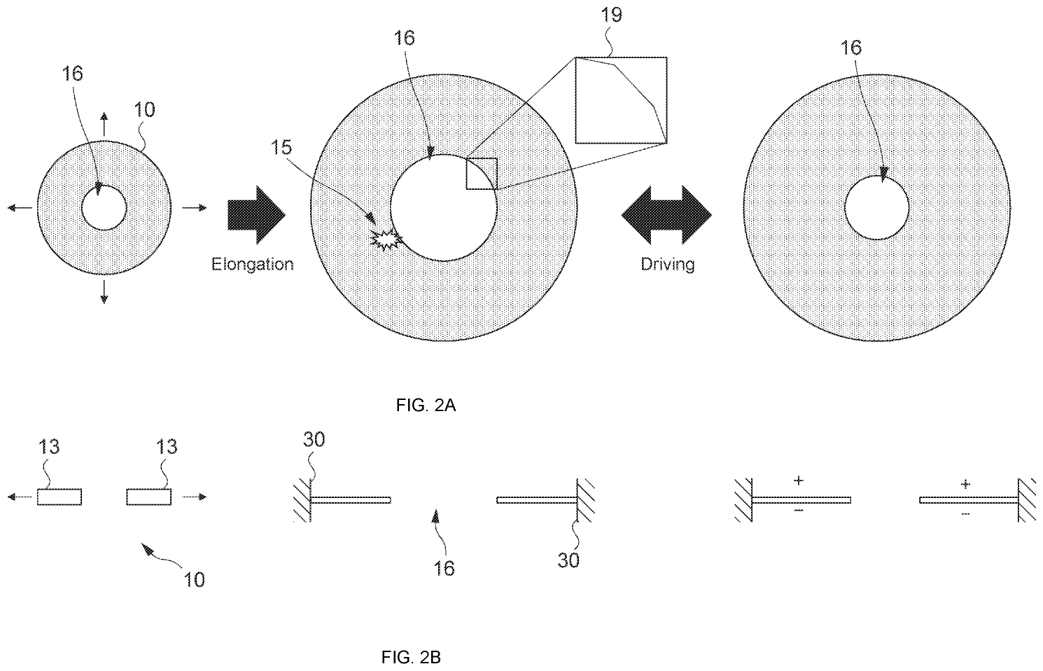

FIG. 1 is a diagram schematically showing a DEA according to the present technology. FIG. 1 is a diagram showing a condition in which a DEA 1 is elongated and driven. A of FIG. 1 is a diagram showing the DEA 1 viewed from above. B of FIG. 1 is a cross-sectional diagram of the DEA 1. Note that a left end diagram of A of FIG. 1 is the cross-sectional diagram of a left end diagram of B of FIG. 1. Similarly, middle and right end diagrams of B of FIG. 1 are the cross-sectional diagram corresponding to middle and right end diagrams of A of FIG. 1. A similar correspondence relationship is applied to FIG. 2.

In this embodiment, the DEA is used as an actuator of a transducer. The DEA has a character that can be driven in a simpler structure as compared to an actuator such as an electromagnetic motor and has a high deformation rate. In addition, the DEA generates great energy on a weight basis and can be produced in a small size and light weight.

In view of the above-described character, the DEA is suitable as an actuator for a lens diaphragm because the DEA can give a sufficiently fast response to a diaphragm mechanism of a lens and is highly quiet since there is no sliding portion.

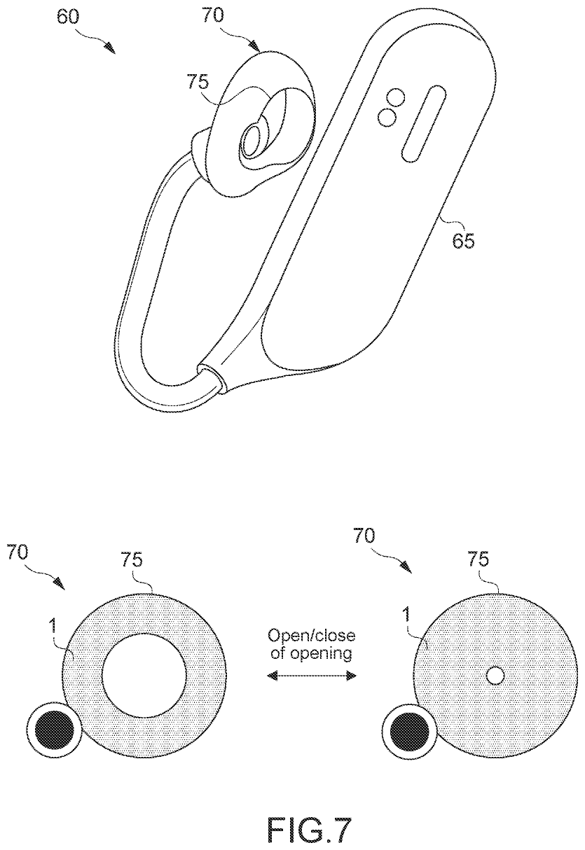

The present invention can be used not only as the actuator for the lens diaphragm but also as a tone adjustment mechanism such as an earphone shown in FIG. 7, an opening/closing mechanism in an ear hole opening earphone, a valve for adjusting a flow rate of gas or liquid, a discharge amount control of a scent material in a smell control device, a haptic device, an antenna sensitivity, a directivity adjustment mechanism, and the like.

As shown in FIG. 1, the DEA 1 has a cylindrical shape extending along an axis 2 direction. In addition, the DEA 1 has both end portions 3 and a central portion 4.

As shown in FIG. 1, the both end portions 3 are regions in which electrodes having at least two electrodes having followability are disposed on both sides of the cylindrical shape in the axis 2 direction. That is, the both end portions 3 correspond to upper and lower ends of the cylindrical DEA 1. The central portion 4 is a region other than the both end portions 3 of the DEA 1.

In this embodiment, the axis 2 corresponds to a predetermined axis.

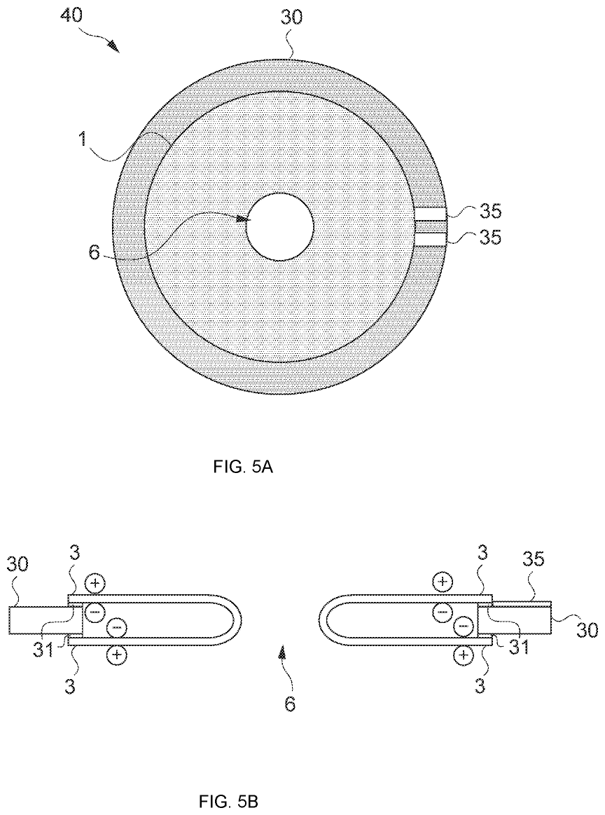

The both end portions 3 are elongated so as to be folded in a direction perpendicular to the axis 2 (arrow 5). In this embodiment, the both end portions 3 are in contact with fixed ends 30 described later with reference to FIG. 5. Furthermore, the both end portions 3 are elongated so as to be substantially parallel to the direction perpendicular to the axis 2. That is, the both end portions 3 have U shapes viewed from the direction perpendicular to the axis 2 by applying a voltage.

The central portion 4 functions as an opening 6 of the DEA 1 by folding the both end portions 3. In this embodiment, the central portion 4 is elongated by applying a voltage to the DEA 1 in the central portion 4.

That is, a diaphragm diameter (opening 6) is adjusted by applying a voltage to the DEA. For example, FIG. 1 shows a condition in which the DEA 1 is driven by applying an arbitrary voltage to the DEA 1 and the opening 6 is elongated in a direction in which the diameter is reduced.

Note that a method of changing a diameter size of the opening 6 is not limited. For example, the diameter may be changed by elongating the both end portions 3, or may be changed by elongating the both end portions 3 and the central portion 4.

The DEA 1 having a cylindrical shape before energizing the electrodes is deformed such that the both end portions are elongated so as to be folded by energizing the electrodes. That is, the deformed DEA 1 has a double donut-shaped structure. In this case, the donut shape is an expression for facilitating understanding, and in the example shown in FIG. 1, no outer side surface exists. That is, although it is described as the donut shape, it does not mean that the both end portions 3 are brought into contact with each other by being folded.

FIG. 2 is a diagram showing a donut-shaped DEA as compared to the present invention. In this case, the donut shape has a side surface, and may be referred to as a Baumkuchen (tree cake) shape. FIG. 2 shows a condition in which a DEA 10 is elongated and driven. A of FIG. 2 is a diagram showing the DEA 10 viewed from above. B of FIG. 2 is a cross-sectional diagram of the DEA 10.

FIG. 2 shows a possibility of using the donut-shaped DEA 10 instead of the cylindrical DEA 1 according to the present invention.

In this embodiment, the DEA 10 of FIG. 2 is produced by punching or by cutting with a laser cutter an outer periphery and a center of a sheet-shaped DEA. As shown in FIG. 2, the DEA 10 has an electrode disposed on the outer peripheral surface 13, and a diameter of an opening 16 is changed by applying a voltage.

In the case of the DEA 10, since an end portion or the opening 16 of the cutting-worked DEA 10 are exposed, the DEA 10 is highly likely to be broken (position 15) by an elongating process or driving. In addition, even if reinforcement such as applying an elastomer to the exposed end portion is performed, hole roundness (see enlarged diagram 19 of FIG. 2) depends on process accuracy, and there is a possibility that expansion and contraction are inhibited due to an increase in the number of non-driving members.

In the present invention, in order to realize a donut shape in which the diaphragm diameter (opening 6) can be adjusted, a diaphragm structure formed by elongating the cylindrical DEA so as to be folded, as shown in FIG. 1. Since a diaphragm portion is formed by elongating the DEA formed into the cylindrical shape, the diaphragm structure having high roundness (see enlarged diagram 9 of FIG. 1) is formed. In addition, since the end portion by cut working the DEA is not exposed, it is possible to suppress a risk of DEA breakage at the time of production or driving.

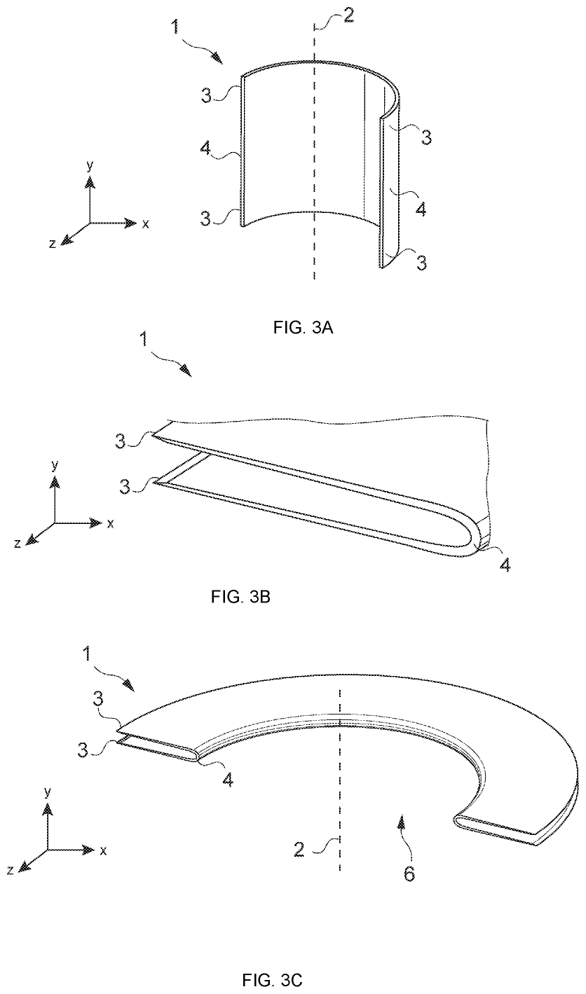

FIG. 3 is a diagram specifically showing elongating and driving of the DEA 1. A of FIG. 3 is a diagram showing the cylindrical DEA before elongating (left end diagram of FIG. 1). B of FIG. 3 is an enlarged diagram of a portion when the DEA is folded (middle diagram of FIG. 1). C of FIG. 3 is a diagram when DEA is driven (right end diagram of FIG. 1).

As shown in A of FIG. 3, the DEA 1 is the cylindrical DEA extending along the axis 2 (Y axis). Note that the DEA 1 is shown with substantially half thereof omitted in B of FIG. 3.

As shown in B of FIG. 3, the both end portions 3 are elongated so as to be folded along an XZ plane. Furthermore, as shown in B of FIG. 3, the both end portions 3 are elongated such that the central portion 4 becomes an outer peripheral portion of the opening 6. As described above, the central portion 4 functions as the diaphragm portion, thereby producing the diaphragm structure in which the roundness of the opening 6 is high.

As shown in FIG. 3C, by applying the voltage to the DEA 1, the both end portions 3 and/or the central portion 4 are elongated to be capable of varying the size of the opening 6. That is, the central portion 4 is driven to approach or move away from the axis 2 along the XZ plane.

Here, an exemplary verification in driving the DEA 1 is described. The DEA 1 was verified under the following conditions:
Physical properties: Young's modulus 1 Mpa, relative dielectric constant 5.5
Initial geometry: cylinder height 2 mm, cylinder diameter 2 mm, thickness 50 μm, inner diameter (diameter of opening 6) 3.70 mm
Applied voltage: 700 V (20 to 70 MV/m)

Under the above conditions, the DEA 1 is driven as follows:
Geometry after elongation: Outer diameter 6 mm, thickness 35 μm to 10 μm
Deformed geometry: Inner diameter 3.48 mm

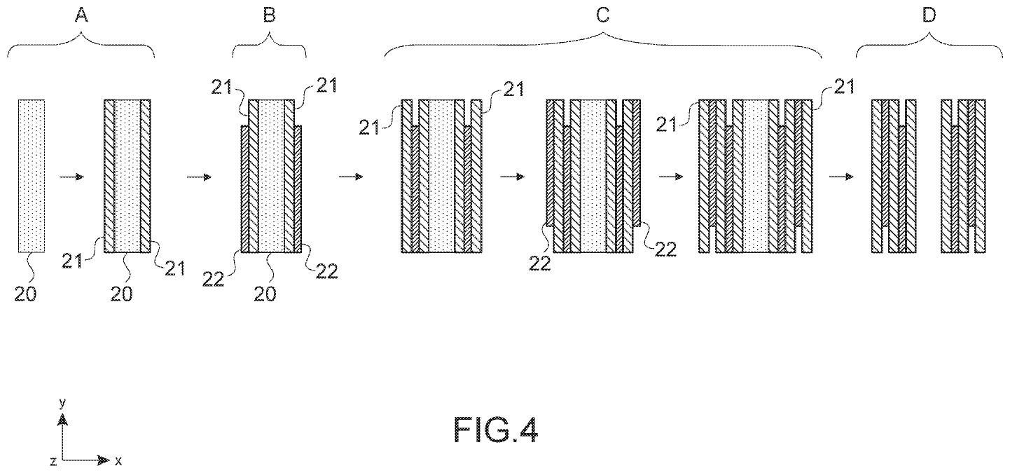

FIG. 4 is a diagram showing a production process of the DEA.

As shown in FIG. 4, the cylindrical DEA 1 is produced by the following steps:

A first step (A of FIG. 4) of depositing an electrode material 21 in the direction perpendicular to the predetermined axis (for example, an XZ plane direction) on a columnar core material 20 extending along the predetermined axis (for example, Y axis);
a second step (B of FIG. 4) of depositing an elastomer 22 in the direction perpendicular to the predetermined axis on the electrode material 21;
a third step (C of FIG. 4) of repeating the first step and the second step described above to deposit the electrode material 21 and the elastomer 22; and
a fourth step (D of FIG. 4) of removing the core material 20 after the DEA having a desired shape is attained and the third step is completed.

In this embodiment, in the third step, the electrode material 21 and the elastomer 22 are deposited at different positions in the predetermined axis direction. For example, as shown in C of FIG. 4, when the elastomer 22 is deposited on a lower end of the DEA 1, the elastomer 22 to be deposited next is deposited on an upper end of the DEA 1.

As the elastomer 22 used in the present invention, an elastic insulating material is used. For example, acrylic rubber, silicone rubber, ethylene-propylene-diene terpolymer (EPDM), natural rubber (NR), butyl rubber (IIR), isoprene rubber (IR), acrylonitrile-butadiene copolymer rubber (NBR), hydrogenated acrylonitrile-butadiene copolymer rubber (H-NBR), hydrin rubber, chloroprene rubber (CR), fluorine rubber, urethane rubber, and the like may be used.

The elastomer 22 may also include additives, if necessary. For example, a crosslinking agent, a plasticizer, an antioxidant, a surfactant, a viscosity modifier, a reinforcing agent, a colorant, and the like may be included.

As the elastomer 22, a silicone rubber having low viscosity and high reliability is desirable.

As a conductive material of the electrodes used in the present invention, for example, a conductive filler and a conductive polymer are used. A shape of the conductive filler include, for example, spherical, elliptical, needle, sheet, scales, tubular, wire, bar (rod), fiber, and irregular shapes. It should be appreciated that it is not limited thereto and various shapes may be used.

Examples of the conductive filler include a carbon-based filler, a metal oxide-based filler, and a metal coating-based filler.

The carbon-based filler includes at least one of carbon black such as Ketjen black and acetylene black, porous carbon, PAN-based carbon fiber, pitch-based carbon fiber, carbon nanofiber, fullerene, graphene, vapor-grown carbon fiber (VGCF), carbon nanotubes such as SWCNT and MWCNT, carbon microcoil, or carbon nanohorn.

The metal-based filler includes, for example, copper, silver, gold, platinum, palladium, nickel, tin, cobalt, rhodium, iridium, iron, ruthenium, osmium, manganese, molybdenum, tungsten, niobium, tantalum, titanium, bismuth, antimony, or lead.

The metal oxide-based filler includes, for example, indium tin oxide (ITO), zinc oxide, indium oxide, antimony-added tin oxide, fluorine-added tin oxide, aluminum-added zinc oxide, gallium-added zinc oxide, silicon-added zinc oxide, zinc oxide-tin oxide, indium oxide-tin oxide, or zinc oxide-indium oxide-magnesium oxide.

The metal-coated filler is obtained by coating a base filler with a metal. The base filler includes, for example, mica, glass beads, glass fiber, carbon fiber, calcium carbonate, zinc oxide, or titanium oxide. The metal coating the base filler includes, for example, nickel and aluminum.

The conductive polymer includes, for example, at least one of polyethylene dioxythiophene/polystyrene sulfonate (PEDOT/PSS), polyaniline, polyacetylene, and polypyrrole.

Note that the conductive material of the electrodes may further include at least one of a binder, a gel, a suspension, and an oil, if necessary. The binder is desirably an elastomer having elasticity. As the elastomer used in the binder, the above-described example is used. The material may also include a composite material. As the composite material, for example, a composite material of at least one of a conductive polymer and a conductive filler and an elastomer, a composite material of an elastic ion conductive material and an electrolyte, a composite material of at least one of a conductive polymer and a conductive filler and a polymer suspension (such as acrylic emulsion), a composite material of at least one of a conductive polymer and a conductive filler and a block copolymer, and a composite material of a polymer gel and an ion conductor are used.

As the conductive material, carbon black or carbon nanotube having high conductivity, which are easy to enhance elasticity even when mixed with a binder (elastomer), are desirable.

[Transducer Configuration]

FIG. 5 is a schematic diagram showing an exemplary configuration of a transducer including the DEA. A of FIG. 5 is a top diagram of a transducer 40. B of FIG. 5 shows a cross-sectional diagram of the transducer 40.

As shown in A of FIG. 5, the transducer 40 has the DEA 1, a fixed end 30, and wiring 35.

In this embodiment, the DEA 1 is elongated such that the both end portions 3 are folded. That is, the DEA 1 is not in a cylindrical shape but in a double donut-shape (see C of FIG. 3).

The fixed end 30 is in contact with the both end portions 3 of the DEA 1 and is disposed to cover the outer periphery of DEA 1 so as to fix the both end portions 3. As shown in B of FIG. 5, in this embodiment, a fixed portion 31 of the fixed end 30 and the both end portions 3 of the DEA 1 are bonded to each other by an adhesive. Specifically, the fixed end 30 may be inserted between upper and lower surfaces of the DEA 1 or may be in contact with only one of the upper and lower surfaces.

As shown in B of FIG. 5, a voltage is applied to the DEA 1 such that the both end portions 3 are elongated and the opening portion 6 of the DEA 1 is driven. Since an end face of the DEA 1 is not exposed as the opening 6, it is possible to reduce a risk of breakage at the time of operation and during processing.

Note that inside of the folded DEA 1 may not be contacted.

In this embodiment, the wiring 35 includes at least two terminals. For example, in order to drive the folded DEA 1, the wiring 35 needs to take out one wire from an outer surface of the DEA 1 and one wire from an inner surface. Note that the wiring 35 may or may not be connected to a substrate.

In addition, for uniformity of expansion and contraction of the transducer 40, the DEA 1 desirably has a point-symmetrical electrode layer pattern with respect to a center of the opening 6 (see B of FIG. 5). Similarly, it is desirable that the outer periphery of the DEA 1 be circular.

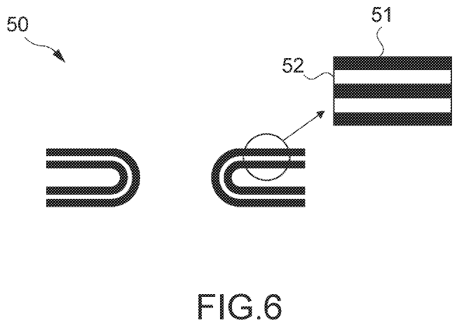

FIG. 6 is a schematic diagram in a case where the DEA includes a plurality of layers of elastomers.

In a DEA 50 shown in FIG. 6, a plurality of electrode layers 51 and a plurality of elastomers 52 are laminated. Note that two or more electrode layers and one or more elastomeric layers may be used as the electrode layers constituting the DEA, but more layers may be laminated. Furthermore, in the case of laminating a plurality of the layers, a voltage is applied alternately (+, −, +, −) from the electrode layers.

Note that shapes of the DEA 1, the opening 6, and the fixed end 30 may not be circular. A surface of the DEA 1 may be coated with a paint or the like that suppresses irregular reflection or transmission. In such cases, it is desirable to reduce stiffness of the paint or to form a thin film so as not to interfere with the operation of the DEA 1.

As described above, the transducer 40 according to this embodiment has the DEA 1 in which the both end portions 3 are elongated in the direction perpendicular to the axis 2 by energizing the both end portions 3 extending along the axis 2 direction in which at least two electrodes having followability are disposed on both sides around the axis 2 in the axis 2 direction. This makes it possible to provide a high degree of freedom in deformation and to suppress a risk of breakage.

In representation of still images and moving images, the diaphragm of the lens is not only a role of adjusting an amount of light to be taken in, but also an indispensable mechanism for the blur representation. In order to realize a smooth blurring effect, the roundness is required for the diaphragm mechanism. For example, a circular diaphragm or the like in which a plurality of wing-shaped light shielding plates are combined has been developed. In addition, in the moving images, a high response and quietness are required. Furthermore, in order to reduce a weight of an entire lens, it is required that the diaphragm be as small and light as possible.

In the present technology, the transducer using the DEA are used as the diaphragm mechanism of the lens. In particular, the DEA has a cylindrical shape and at least two electrodes having followability are disposed on both sides. When the electrodes are energized, both end portions are elongated so as to be folded.

As a result, the diaphragm structure having the high roundness can be produced. Furthermore, since the cutting-worked end portions of the DEA are not exposed, it is possible to suppress the risk of the DEA breakage at the time of production or driving. In addition, since the actuator itself is used as the diaphragm mechanism, it is possible to reduce the size and weight, simplify an assembly process, and improve the quietness. In addition, since the DEA is used as the actuator, it is possible to further reduce the size weight, and improve the quietness.

### Other Embodiments

The present technology is not limited to the embodiments described above, and can achieve various other embodiments.

In the above-described embodiments, the transducer 40 is used as the diaphragm mechanism of the lens. It is not limited thereto, and the transducer 40 may be used in various applications.

FIG. 7 is a schematic diagram showing an earphone deformable in an ear hole.

As shown in FIG. 7, an earphone deformable in an ear hole 60 includes a speaker unit 70.

The earphone deformable in the ear hole 60 can be worn on an ear of a user, and can make various sounds from the speaker unit 70 by using a remote control or a driver unit 65.

In this embodiment, the speaker unit 70 has an opening 75, and the DEA 1 according to the present invention is used as an opening/closing function of the opening 75. That is, an outer peripheral portion of the opening 75 corresponds to the fixed end 30 in FIG. 5.

The opening 75 is basically opened such that surrounding sounds can be heard. When the user wants to block the surrounding sounds, such as when the user wants to concentrate on music, the opening 75 is driven to close as shown in FIG. 7. For example, when the user selects a sound insulation mode that blocks ambient sound, the electrodes at both end portions (not shown) of DEA 1 are energized and the opening 75 is driven to close.

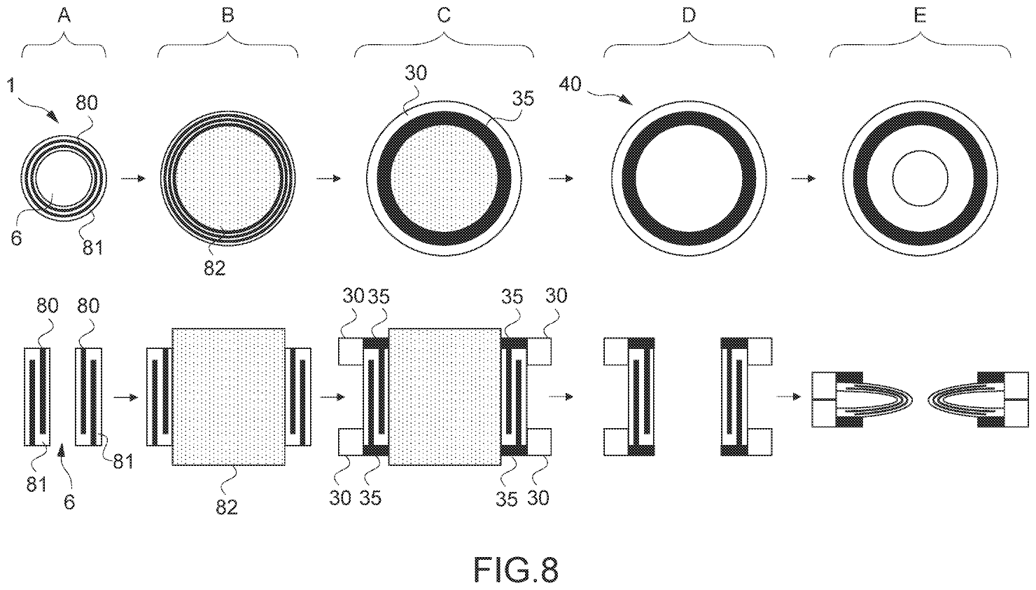

FIG. 8 is a schematic diagram showing a method of elongating and producing the transducer 40.

As shown in FIG. 8, a method of elongating and producing the transducer 40 will be described by five steps (Steps A to E). In FIG. 8, upper and lower diagrams corresponding to respective steps are cross-sectional diagrams and diagrams viewed from above in the respective steps.

In Step A, the cylindrical DEA 1 is made (see FIG. 4). In this embodiment, in the DEA 1, two layers of elastomers 80 are laminated. In addition, three layers of the electrode material 81 are laminated. That is, in Step A of FIG. 8, the DEA in which the fourth step of FIG. 4 is completed is shown.

In Step B, a jig 82 is inserted into the opening 6 of the DEA 1.

In Step C, the fixed end 30 and the wiring 35 are attached to the outer peripheral portion of the DEA 1.

In Step D, the inserted jig 82 is pulled out. As a result, the transducer 40 shown in FIG. 5 is produced.

Step E is a diagram when the transducer 40 is elongated. Specifically, the DEA 1 bends due to a shrinkage force of the DEA 1. As a result, the shape of the DEA 1 is changed from cylindrical to doughnut.

At least two of the features of the present technology described above can also be combined. In other words, various features described in the respective embodiments may be combined discretionarily regardless of the embodiments. Furthermore, the various effects described above are not limitative but are merely illustrative, and other effects may be provided.

The present technology may also have the following structures.

(1) A transducer, including:
an elastomer extending along a predetermined axis direction and having both end portions in which at least two electrodes having followability are disposed on both sides around a predetermined axis in the predetermined axis direction, the both end portions being elongated to be folded in a direction perpendicular to the predetermined axis.
   (2) The transducer according to (1), further including:
a central portion in a region different from the both end portions of the elastomer, in which the central portion is elongated so as to approach the predetermined axis by energizing the electrodes.
   (3) The transducer according to (1), in which
the both end portions located in the same direction with respect to the predetermined axis are elongated so as to be substantially parallel to the predetermined axis by energizing the electrodes.
   (4) The transducer according to (3), in which
the elastomer has a donut shape viewed from the predetermined axis direction when the both end portions are elongated so as to be folded in the direction perpendicular to the predetermined axis.
   (5) The transducer according to (1), in which
the elastomer has a cylindrical shape extending along the predetermined axis direction and has an opening in the predetermined axis direction, and
the central portion is elongated so as to change a diameter size of the opening by energizing the electrodes.
   (6) A method of producing a transducer, including:
a first step of depositing an electrode material in a direction perpendicular to a predetermined axis with respect to a cylindrical core material extending along the predetermined axis;
a second step of depositing an elastomer on the electrode material in the direction perpendicular to the predetermined axis; and
a third step of repeating the first step and the second step to deposit the electrode material and the elastomer.
   (7) The method of producing the transducer according to (6), in which
in the third step, the electrode material and the elastomer are deposited at different positions in the predetermined axis direction.
   (8) The method of producing the transducer according to (6), further including:
a fourth step of removing the core material after the third step is completed.

### REFERENCE SIGNS LIST

1 DEA
2 axis
3 both end portions
4 central portion
6 opening
21 electrode material
22 elastomer
40 transducer

1. A transducer, comprising:
an elastomer extending along a predetermined axis direction and having both end portions in which at least two electrodes having followability are disposed on both sides around a predetermined axis in the predetermined axis direction, the both end portions being elongated to be folded in a direction perpendicular to the predetermined axis.

2. The transducer according to claim 1, further comprising:
a central portion in a region different from the both end portions of the elastomer, wherein
the central portion is elongated so as to approach the predetermined axis by energizing the electrodes.

3. The transducer according to claim 1, wherein
the both end portions located in the same direction with respect to the predetermined axis are elongated so as to be substantially parallel to the predetermined axis by energizing the electrodes.

4. The transducer according to claim 3, wherein
the elastomer has a donut shape viewed from the predetermined axis direction when the both end portions are elongated so as to be folded in the direction perpendicular to the predetermined axis.

5. The transducer according to claim 1, wherein
the elastomer has a cylindrical shape extending along the predetermined axis direction and has an opening in the predetermined axis direction, and
the central portion is elongated so as to change a diameter size of the opening by energizing the electrodes.

6. A method of producing a transducer, comprising:
a first step of depositing an electrode material in a direction perpendicular to a predetermined axis with respect to a cylindrical core material extending along the predetermined axis;
a second step of depositing an elastomer on the electrode material in the direction perpendicular to the predetermined axis; and
a third step of repeating the first step and the second step to deposit the electrode material and the elastomer.

7. The method of producing the transducer according to claim 6, wherein
in the third step, the electrode material and the elastomer are deposited at different positions in the predetermined axis direction.

8. The method of producing the transducer according to claim 6, further comprising:
a fourth step of removing the core material after the third step is completed.
